(19) United States
(12) Patent Application Publication
(10) Pub. No.: US 2013/0340681 A1
(43) Pub. Date: Dec. 26, 2013

(54) REDUCED PRESSURE PROCESSING CHAMBER AND EXHAUST ARRANGEMENT

(71) Applicant: TEL Solar AG, Trubbach (CH)

(72) Inventors: Philipp WAGNER, Bad Ragaz (CH); Eduard ILINICH, Jona (CH); Damian EHRENSPERGER, Basel (CH)

(21) Appl. No.: 13/921,782

(22) Filed: Jun. 19, 2013

Related U.S. Application Data
(60) Provisional application No. 61/662,415, filed on Jun. 21, 2012.

(51) Int. Cl. C23C 16/44

(52) U.S. Cl. CPC C23C 16/4412
USPC 118/723 R; 118/715

(57) ABSTRACT

An improved reinforcement and exhaust arrangement is provided for a reduced pressure processing chamber. The arrangement is particularly advantageous for plasma processing chambers of large substrates (one square meter or larger) under a reduced pressure. The arrangement includes channels formed along sidewalls of the process chamber, and into which exhaust outlets from the chamber communicate. The channels provide support to the sidewalls and convey the exhaust gases to a port at a location at which the gases can be conveniently pumped from the system. In an example, plural outlets from the chamber are in communication with a common channel or channels which provide a flow path to a single exhaust port. As a result, although plural outlets extend from the interior of the chamber to the exterior of the chamber, only a single connection to the exhaust pump need be provided.

### CROSS-REFERENCE TO RELATED APPLICATIONS

This application claims priority application to provisional application 61/662,415, filed Jun. 21, 2012, the entirety of which is incorporated herein by reference.

### TECHNICAL FIELD

The invention relates to reduced pressure processing systems such as plasma processing systems, and particularly to an improved support or reinforcement and exhaust arrangement for plasma processing systems that operate in a vacuum or reduced (sub-atmospheric) pressure.

### BACKGROUND

Plasma processing systems are known for various operations in processing substrates. For example, plasma enhanced chemical vapor deposition (PECVD) systems are advantageously used, for example, in depositing thin films for flat panel displays, photovoltaic cells or modules, or OLEDs. For example, silicon or silicon compounds such as Si, SiOx, or SiN based films are formed using process gases (e.g., silane, dopants, hydrogen, etc.) that are excited to form a plasma. Plasma processing systems can be used for other processes such as etching.

FIG. 1 schematically represents a PECVD system having an enclosure or chamber 1 and a pair of essentially flat planar electrodes 2, 3. Such an arrangement is described, for example, in U.S. Pat. No. 6,228,438. The electrodes are connected to one or more suitable power supplies, such as an RF/VHF power supply (not shown) by connectors represented at 7, 8. In addition, a substrate 4 is positioned on the electrode 3. A gas supply 5 and exhaust 6 are schematically represented, however it is to be understood that the supply and exhaust can have various forms.

Such an arrangement can be used, for example, to deposit silicon compounds on glass substrates, for example, substrates having dimensions of 1100-1300 mm or 1.4 m², by way of example. As shown, an inter-electrode gap IEG is provided as a space between the two electrodes, while the plasma gap PG is provided between the top of the substrate 4 and the bottom of the upper electrode 2. By way of example, a standard gap size can be approximately 30 mm, however very small gaps of below 10 mm can be desirable. As should be apparent, the plasma gap PG is effectively the IEG minus the thickness of the substrate 4.

Such systems can be in the form of single reactor or single chamber systems, but also can be part of larger systems having multiple reactors which simultaneously perform CVD processes on other substrates in parallel. In addition, such chambers or reactors can be provided in in-line or cluster configurations. Two types of reactor arrangements are also commonly known, including a one-reactor-single-wall chamber type, and a box (or boxes)-in-box arrangement. In the one-reactor-single-wall chamber type, the walls of the reactor or chamber form the vacuum or reduced pressure volume within which the processing takes place, and an ambient or approximately atmospheric pressure surrounds the outside of the reactor. In the box-in-box arrangement, the reactor box provides a processing region that is located within the outer walls of another chamber to form a separate outer enclosure, and the outer enclosure can be maintained at a reduced pressure. In addition, plural reactors can be provided in the outer chamber for batch processing of plural substrates. See, for example, U.S. Pat. Nos. 4,989,543 and 5,693,238.

Particularly when processing large substrates (for example, where the lower electrode or substrate support is configured to support substrates which are one square meter or larger) with a vacuum or reduced pressure (sub-atmosphere) in the chamber, large forces can be present on the exterior walls of the chamber. If the walls of the entire chamber are made thick, the cost of such an arrangement can be expensive, particularly for a chamber large enough for processing large substrates, and where a system can include a plurality of such chambers.

An additional difficulty with existing systems is that typically plural outlet or pumping ports are provided for removal of exhaust gases from the system. Particularly for large systems for large substrates, a single exit port from the system is typically not sufficient, and therefore, plural ports, for example, four ports, are provided. However, a difficulty with this arrangement is that fittings, seals, connectors, etc. must be provided at each exhaust port location, and moreover, suitable tubing or piping must then connect the ports to exhaust pumps. In addition, the location of the exhaust ports might not be convenient from a standpoint of providing a compact design or from a standpoint of not interfering with other utilities or access for maintenance.

The present invention overcomes the above deficiencies of known arrangements.

### SUMMARY OF THE INVENTION

The present invention provides advantageous features from a standpoint of providing improved chamber support and also from a standpoint of providing an improved exhaust handling arrangement. It is to be understood that the embodiments described herein include various advantageous features which can be used alone or in combination. However, the invention is not limited to the particular embodiments described therein, as embodiments could be constructed which utilize certain features but not others.

In accordance with a particularly preferred arrangement, a chamber reinforcement is combined with handling of the exhaust to provide an arrangement which enhances the strength of the chamber while also providing for more convenient handling of the exhaust of process gases. The arrangement is provided within or on an exterior of the outer wall of the process chamber, and provides one or more channels which extend along at least one of the process chamber walls. In addition, preferably the channel is in communication with an aperture extending from an interior of the chamber to thereby provide communication of the channel with exhaust exiting from the chamber. Accordingly, in addition to improving support of the chamber, the channel conveys exhaust gases from an exhaust port to a location at which the exhaust can be more conveniently coupled to an exhaust pump. Thus, it is not required to connect the exhaust pump directly to the location at which the exhaust exits the chamber.

In accordance with an additional feature of the invention, one or more channels can be in communication with plural exhaust ports from the chamber, with the channel or channels providing a flow path to a common pumping port. As a result, one exhaust outlet from the system can be used for plural exhaust outlets exiting from the chamber. In addition, the exhaust outlet or pumping port from the system can be provided at a location which is more convenient from a standpoint of the chamber design, location of the exhaust pump, or in terms of minimizing interference with other operations. Further, providing a flow path from plural outlets from the chamber to one exhaust port for the system reduces the number of overall system outlets, so that the number of fixtures associated with coupling of plural outlets to one or more pumps can be reduced, thereby saving cost and also reducing maintenance. In addition, by providing the exhaust outlet at a location more desirable with regard to the location of the exhaust pump, pump loses can be reduced.

### BRIEF DESCRIPTION OF THE DRAWINGS

A better appreciation of the invention will become apparent from the description herein, particularly when considered in conjunction with the drawings, in which:

FIG. 1 is a schematic representation of a conventional plasma processing arrangement; and

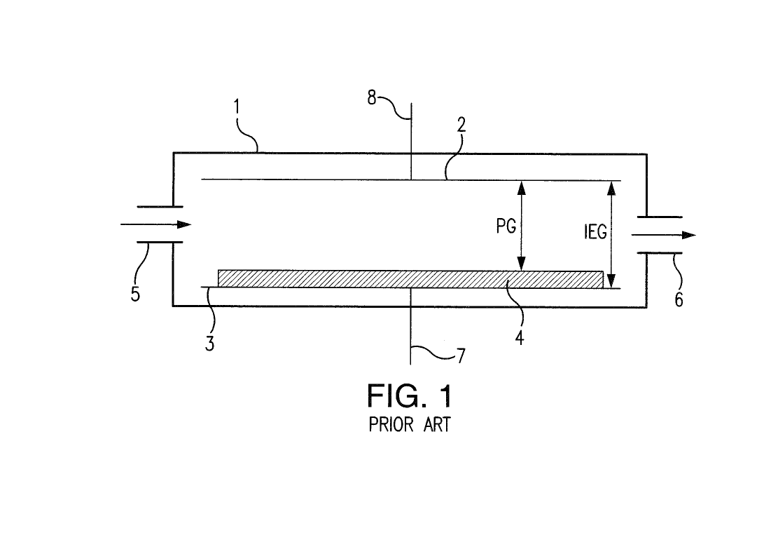

FIGS. 2A and 2B illustrate features of a plasma chamber in accordance with the present invention.

### DETAILED DESCRIPTION

A better appreciation of the invention will be apparent from the following detailed description, in which like reference numbers are used for the same or similar parts throughout the different views. The present invention is particularly advantageous for plasma processing substrates, for example, in a PECVD system, however, it is to be understood that the invention could be used for other types of processing systems, for example in etching or other types of deposition systems. In addition, the invention is particularly advantageous for large substrates, for example, in which the substrate support or lower electrode is configured to support substrates of one square meter or larger. However, the invention could also be applied to systems for processing of substrates of other sizes.

As discussed earlier, particularly where large substrates are processed in a reduced pressure environment, substantial forces can be present on the exterior walls of such a chamber, and moreover, the exhaust removal arrangements for such systems have been less than fully satisfactory.

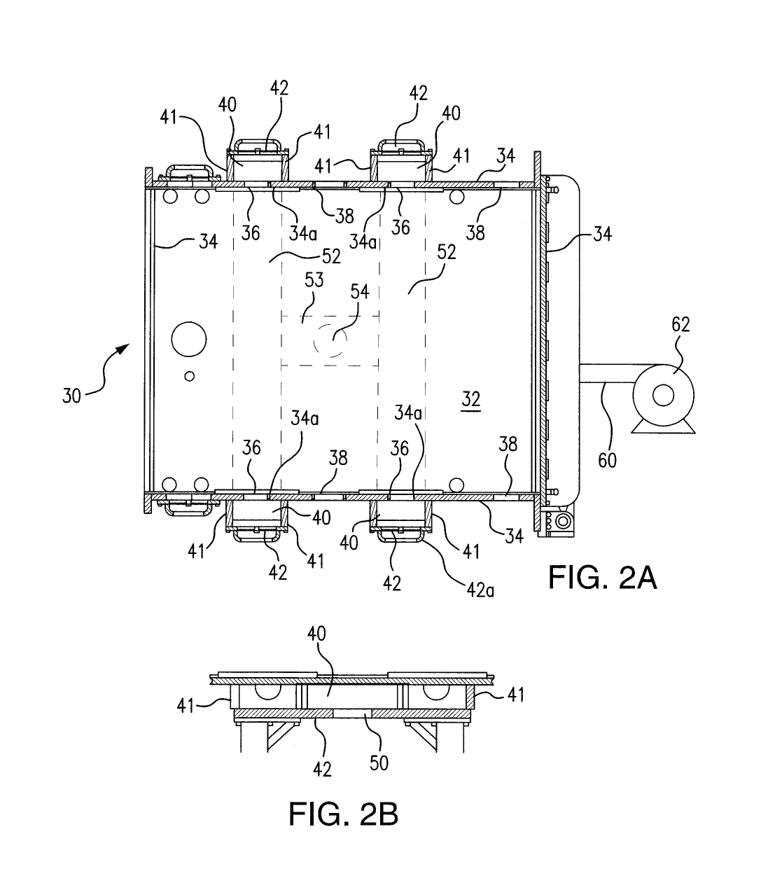

FIG. 2A is a horizontal cross-section through a chamber in accordance with the invention. In such an arrangement, by way of example, the substrate is fed or loaded through an inlet, for example, represented at 30, and the substrate is deposited on a floor or lower electrode at the bottom of the chamber 32. Process gases are injected into the system, for example, by way of a shower head electrode or other gas inlet arrangement, and the process gases are excited into a plasma by application of power to one or more electrodes, for example, RF power. The plasma is then used to process the substrates, for example, to deposit a film or layer upon a glass substrate.

In the illustrated example, chamber walls 34 define a processing volume therein (together with the top and bottom of the chamber), and the chamber operates at a sub-atmospheric pressure or reduced pressure. Due to the size of such systems, plural exhaust outlets are provided which are then pumped by an exhaust pump coupled to each exhaust outlet. In the illustrated arrangement, four exhaust outlets 36 are provided from the chamber. However, in the arrangement shown, rather than connecting each opening or exhaust port 36 to an exhaust pump or vacuum pump, the exhaust ports each extend into support channels as discussed below.

Other apertures can also be provided in the chamber wall 34, for example, to provide access for other utilities such as providing an inlet and outlet for a cooling medium for cooling the lower electrode, or for providing an inlet for power, etc. Such additional inlet/outlet apertures are illustrated at 38.

In the illustrated arrangement, the exhaust ports 36 communicate with one or more channels represented at 40. The channels are formed by an enclosure which, when viewed in cross-section, can be seen as including sidewalls 41. By way of example, the sidewalls 41 can be in the form of ribs extending along the outer surface of an outer wall 36 of the chamber. In the illustrated arrangement, the channels, and the walls forming the channels extend vertically along the sidewall 34. However, alternate configurations could be provided, for example, in which the channels (or portions of channels) extend horizontally (or in other words perpendicular to the arrangement illustrated). In addition, defining the channels 40, a top or cover 42 is provided. Sometimes, chambers include pre-existing ribs extending along the walls, and in this case, it could be possible to form the channels 40 by adding a top or cover 42 as well as structures forming the ends of the channels to form the channel enclosure. The top or cover 42 can be removable or openable, for example, to allow for cleaning. Forming the bottom, or wall opposite to the cover, is a portion of the outer surface of the chamber wall itself 34a.

As should be apparent, the channels can be provided in various ways. For example, if existing ribs are present on a chamber wall, they can be provided with a cover to form channels. Alternately, ribs or side walls 41 can be easily added to an exterior of a chamber and provided with a cover, or such structures can be provided as original equipment. As a further alternative, one or more parts of the channel structure can be integrally formed with the chamber wall, for example, by casting a wall structure that includes channels for both reinforcement and gas flow, or a combination of the above expedients can be utilized. Thus, the channel could also be formed within or partially within the chamber wall and integral therewith, so that the channel extends along the chamber wall 34. As should be apparent, such an arrangement provides an exterior support or exterior skeleton for improving the strength and support of the chamber walls 34, and thereby, improving the integrity or strength of the system. The arrangement also provides for improved handling of exhaust gases as discussed hereinafter.

FIG. 2B is an enlarged cross-sectional view of a lower portion of the chamber, and particularly the channel and cover arrangement, at a location lower than FIG. 2A so as to show a pumping outlet from the channel. The sidewalls or ribs 41 can have various forms, for example, with beam members illustrated in the FIG. 2B arrangement or as solid ribs. In addition, the cover 42 can be provided on the outermost surfaces of the side walls or ribs 41. Alternately, the cover 42 could extend between the ribs, which would reduce the size of the channels. A handle 42a can be provided on the cover 42 if desired, for example, to ease removal of the cover for cleaning As shown in FIG. 2B, the cover can have an outlet 50 extending therethrough. Thus, exhaust gases can exit through exhaust outlet 36, then pass along the channel 40 and be exhausted through outlet 50 which is coupled to a suitable vacuum or exhaust pump. An exhaust port or pumping port 50 can be provided for each channel to exhaust gases from that channel. This arrangement is advantageous from a standpoint of exhaust handling in that the outlet 50 is positioned at a location more convenient for coupling to the exhaust or vacuum pump, whereas outlets 36 are positioned at a location best suited for communication from the interior of a chamber to the exterior of the chamber. For example, the port 50 can be provided vertically above or below the location of outlet 36, depending on the location of the pump or the overall system design. Moreover, the channels 40 provide two functions in combination, in that they enhance the strength or integrity of the chamber, while also improving the exhaust handling, and significantly reduce the space requirements, because no additional vacuum or exhaust piping is necessary.

An exhaust or pump outlet 36 can be associated with each channel 40. Alternatively, plural outlets 36 can be in communication with one channel. For example, a channel or channel portion could extend horizontally to cover two outlets 36. In accordance with a further preferred feature of the invention, channels can be connected or can be provided to include a common or connecting channel, so that gases exiting from plural chamber outlets 36 can be pumped from a single exhaust port by a single vacuum pump, and the pump port or exhaust port can be provided at a location more convenient in terms of the location of the vacuum pump and/or other operations or utilities associated with the chamber. For example, in the arrangement illustrated in FIG. 2A, the channels 40 can extend vertically downward along the wall 34 of the chamber, and then communicate with additional channels or connecting channels 52 extending along the bottom of the chamber as represented in a broken line in FIG. 2A. Each of these channels 52 can then communicate with a further channel or connecting channel 53 which includes outlet exhaust port or pumping port 54 which can be connected to a vacuum pump. Thus, as should be apparent, rather than requiring four connections to the exhaust outlets 36, only a single connection at 54 can be utilized, significantly reducing the amount of fixtures, seals, couplings, etc. that are needed. In addition, the outlet 54 can be provided at a location at which pump loses are minimized, at which interference with other operations is minimized and/or at a location which provides a more appealing design. If desired, the arrangement to provide one or more connecting channels 52, 53 to a common pumping port could also be provided at the top of the chamber, with an outlet or pumping port 54 at the top of the chamber. As another alternative, for example, one larger channel could be provided on the bottom (or top) of the chamber, into which each of the channels 40 feed, with pumping port 54 extending from the single connecting channel. Alternate configurations and pumping port locations could be used. A suitable conduit or flexible tubing 60 can connect the pumping port 54 (or 50) to a pump 62.

As should be apparent, modifications and variations are possible, and therefore, the present invention should not be construed as limited to the embodiments illustrated and described herein.

What is claimed is:

1. A vacuum chamber comprising:
an enclosure including at least one wall defining a process volume to contain one or more process gases at a sub-atmospheric pressure, the enclosure comprising one or more exhaust ports that form an opening extending from the process volume and through the at least one wall;
one or more enclosed reinforcement elements coupled to or formed into the at least one wall of the enclosure, and configured to strengthen at least a portion of the enclosure to resist stress caused by the sub-atmospheric pressure, wherein the one or more enclosed reinforcement elements comprise:
at least one channel to convey process gases exiting from the process volume through the one or more exhaust ports;
a pump port to evacuate the process gases from the at least one channel, and that can be coupled to a pump system.

2. A vacuum chamber according to claim 1, wherein at least part of an inner surface of the at least one channel is formed by an outer surface of the at least one wall of the enclosure.

3. A vacuum chamber according to claim 2, wherein a plurality of exhaust ports extend from the process volume to the at least one channel, and wherein one pump port evacuates process gases exiting from the process volume through the plurality of exhaust ports after the process gasses pass through the at least one channel.

4. A vacuum chamber according to claim 1, wherein at least part of the at least one channel extends vertically along the at least one wall of the enclosure, and wherein the pump port is vertically spaced from a location of the one or more exhaust ports, and wherein the pump port is connected to a vacuum pump.

5. A vacuum chamber according to claim 1, wherein the vacuum chamber is a plasma processing chamber.

6. A vacuum chamber according to claim 1, wherein the at least one wall comprises:
a first wall having a first exhaust port extending therethrough; and
a second wall having a second exhaust port extending therethrough;
wherein the at least one channel includes:
a first channel extending along at least a portion of the first wall, and wherein the first exhaust port opens into the first channel such that process gases exit from the process volume through the first exhaust port into the first channel; and
a second channel extending along at least a portion of the second wall, and wherein the second exhaust port opens into the second channel such that process gases exit from the process volume through the second exhaust port into the second channel.

7. A vacuum chamber according to claim 6, wherein the at least one channel further includes:
at least one connecting channel, wherein the at least one connecting channel is in communication with both the first channel and the second channel, and wherein the pump port extends from the at least one connecting channel so that process gases passing through both the first channel and the second channel exit the system through the pump port.

8. A vacuum chamber according to claim 7, wherein each of the first and second channels comprise four walls, said four walls including:
first and second channel side walls protruding from an outer surface of the enclosure;
a third channel wall spaced from the outer surface of the enclosure, said third channel wall extending from the first channel side wall to the second channel side wall; and
a fourth channel wall provided by a portion of the outer surface of the enclosure which extends between the first channel side wall and the second channel side wall.

9. A vacuum chamber according to claim 1, wherein the at least one wall includes a side wall of the enclosure, and wherein the at least one channel comprises:
first and second channel side walls protruding from the side wall of the enclosure;
a third channel wall spaced from the side wall of the enclosure, said third channel wall extending from the first channel side wall to the second channel side wall; and
a fourth channel wall provided by a portion of an outer surface of said side wall of said enclosure which extends between the first channel side wall and the second channel side wall.

10. A vacuum chamber according to claim 9, wherein the third channel wall comprises a cover which can be opened or removed to provide access to inside of the channel.

11. A vacuum chamber according to claim 1, wherein the one or more exhaust ports from the process volume comprise four exhaust ports, and wherein the at least one channel comprises four channels, and wherein the four exhaust ports each opens into a respective one of the four channels.

12. A vacuum chamber according to claim 11, where gases from all four channels exit the system through a single pump port, and wherein the single pump port is connected to a vacuum pump.

13. A system comprising:
a process chamber having a process volume therein and configured to process at least one substrate having a large planar surface area, the process chamber comprising a chamber wall to contain one or more process gases used to etch the substrate or deposit a film on the substrate in the process volume, the chamber wall comprising:
an inner surface;
an outer surface; and
one or more openings through the chamber wall through which the process gases pass to exit from the process volume;
wherein the system further includes at least one enclosure along the outer surface of the chamber wall that forms a channel defining a flow path between at least one of the one or more openings and an outlet port of the enclosure; and
a vacuum pump coupled to the outlet port to remove process gases through the outlet port.

14. The system of claim 13, wherein the channel includes an inner surface which comprises a portion of the outer surface of the chamber wall.

15. A system according to claim 13, wherein at least part of the one channel extends vertically along the outer surface of the chamber wall.

16. A system according to claim 15, wherein the enclosure includes an openable cover.

17. A system according to claim 13, wherein the one or more openings include a first opening and a second opening, and wherein the at least one enclosure includes a plurality of channels comprising:
a first channel which receives process gases exiting the process volume through the first opening; and
a second channel which receives process gases exiting the process volume through the second opening; and
wherein process gases from both the first channel and the second channel exit the system through the outlet port.

18. A system according to claim 17, further including at least one connecting channel which is in communication with the first channel and the second channel, and wherein the outlet port extends from the at least one connecting channel.

19. A process gas container comprising:
a plurality of reinforcement ribs along an outside surface of the process gas container;
one or more openings in the process gas container with at least one of the one or more openings disposed between at least two of the reinforcement ribs; and
a channel along the outside surface of the process gas container, the channel comprising:
a first side wall comprising at least one of the reinforcement ribs;
a second side wall comprising at least one other of the reinforcement ribs;
a third wall extending from the first side wall to the second side wall and which is spaced from the outside surface of the process gas container, and wherein at least part of the third wall can be selectively separated from the channel to open the channel and provide access to the channel;
a fourth wall comprising a portion of the outside surface of the process container;
at least one of the one or more openings in the process gas container extending into the channel; and
an outlet coupled to a pump and which pumps gases from said channel.

20. A process gas container according to claim 19, wherein the container is a plasma processing chamber, and wherein at least two of said channels are provided, and wherein process gases are removed from both of the channels through said outlet coupled to said pump.
